(19) United States
(12) Patent Application Publication
(10) Pub. No.: US 2024/0215649 A1
(43) Pub. Date: Jul. 4, 2024

(54) MEMS SENSOR, MEMS MICROPHONE, ELECTRONIC CIGARETTE

(71) Applicant: AAC ACOUSTIC TECHNOLOGIES (SHENZHEN) CO., LTD., Shenzhen (CN)

(72) Inventors: Jinyang Li, Shenzhen (CN); Rui Zhang, Shenzhen (CN)

(21) Appl. No.: 18/454,041

(22) Filed: Aug. 22, 2023

Related U.S. Application Data
(63) Continuation of application No. PCT/CN2023/084847, filed on Mar. 29, 2023.

(30) Foreign Application Priority Data
Dec. 29, 2022 (CN) 202223599021.9

(51) Int. Cl. A24F 40/51; A24F 40/10; A24F 40/40; B81B 3/00; H04R 1/02; H04R 7/04; H04R 19/04

(52) U.S. Cl. CPC A24F 40/51; A24F 40/10; A24F 40/40; B81B 3/0021; H04R 1/028; H04R 7/04; H04R 19/04; B81B 2201/0257; B81B 2201/0292; B81B 2203/0127; B81B 2203/019; H04R 2201/003

(57) ABSTRACT

A MEMS sensor, includes a substrate with a back cavity, and a capacitive system arranged on the substrate, the MEMS sensor includes a first back plate assembly and a diaphragm opposite to the first back plate assembly. The first back plate assembly includes a first back plate and a second back plate, the first back plate includes a plurality of a first back plate holes, the second back plate includes a plurality of a second back plate holes, each first back plate hole and each second back plate hole are staggered with each other in a vibration direction of the diaphragm. Compared with the related art, the MEMS sensor disclosed by the present disclosure could play a good dustproof effect.

### TECHNICAL FIELD

The present disclosure relates to a field of sensor technology, in particular to an MEMS sensor, and a micro-electro-mechanical system (MEMS) microphone and an electronic cigarette using same.

### BACKGROUND

The MEMS sensor in the related art includes a substrate with a back cavity and a capacitive system arranged on the substrate, the capacitive system includes a back plate and a diaphragm arranged opposite to the back plate. The strength of the back plate is important to the reliability of the MEMS sensor. In addition, the back plate is provided with several through-holes, which will further reduce the strength of the back plate and thus affect the reliability of the product.

Thus, it is necessary to provide a MEMS sensor to solve the problem.

### SUMMARY

In view of the above, an objective of the present disclosure is to provide a dust-proof MEMS sensor.

In order to achieve the objective mentioned above, the present disclosure discloses a MEMS sensor, including:
a substrate with a back cavity, and
a capacitive system arranged on the substrate, comprising a first back plate assembly and a diaphragm opposite to the first back plate assembly, wherein
the first back plate assembly comprises a first back plate and a second back plate, the first back plate is spaced apart from the second back plate, the first back plate comprises a plurality of a first back plate holes, the second back plate comprises a plurality of a second back plate holes, each first back plate hole and each second back plate hole are staggered with each other in a vibration direction of the diaphragm.

A MEMS microphone, comprises:
a shell,
a base enclosed with the shell to form an accommodation space, and
the MEMS sensor as described above located in the accommodation space, wherein
the MEMS sensor is fixed with the base, a sound inlet hole is formed in the shell or the base.

As an improvement, the sound inlet hole is formed in the shell, the first back plate assembly is located on a side of the diaphragm far away from the substrate.

As an improvement, the sound inlet hole is formed in the base, the sound inlet hole is in communication with the back cavity, the first back plate assembly is located on a side of the diaphragm close to the base.

An electronic cigarette, comprises,
a housing with a smoking port passing through an upper end thereof,
an atomizer received in the housing and spaced apart from the smoking port,
an e-liquid chamber located between the atomizer and the smoking port,
a first receiving space communicating with the smoking port, and
an MEMS air flow sensor located in the first receiving space, wherein
the MEMS air flow sensor comprises a printed circuit board, a frame connected with the printed circuit board to form a second receiving space, the MEMS sensor as described above is fixed with the printed circuit board, the frame comprises a first through hole in communicating with the first receiving space and the second receiving space, a second through hole is formed in the printed circuit board and in communicating with the back cavity and the outside.

As an improvement, a distance between the first back plate and the second back plate is smaller than 1 μm.

As an improvement, the capacitive system further comprises a second back plate assembly, the first back plate assembly and the second back plate assembly are located on each side of the diaphragm, the second back plate assembly comprises a third back plate and a fourth back plate spaced from each other, a plurality of a third back plate holes are formed in the third back plate, a plurality of a fourth back plate holes are formed in the fourth back plate, the third back plate holes and the fourth back plate holes are staggered with each other in the vibration direction of the diaphragm.

As an improvement, a distance between the third back plate and the fourth back plate is smaller than 1 μm.

### BRIEF DESCRIPTION OF DRAWINGS

FIG. 1 is a cross-sectional view of the MEMS sensor in accordance with an exemplary embodiment of the present disclosure;

FIG. 2 is a cross-sectional view of the MEMS microphone in accordance with an embodiment;

FIG. 3 is a cross-sectional view of the MEMS microphone in accordance with another embodiment;

FIG. 4 is a cross-sectional view of the electronic cigarette in accordance with an exemplary embodiment of the present disclosure;

FIG. 5 is a cross-sectional view of the MEMS air flow sensor in FIG. 4 in accordance with an embodiment;

FIG. 6 is a cross-sectional view of the MEMS sensor in FIG. 5 in accordance with another embodiment.

### DESCRIPTION OF EMBODIMENTS

The technical solutions in embodiments of the present disclosure will be described clearly and completely below with reference to the accompanying drawings in the embodiments of the present disclosure.

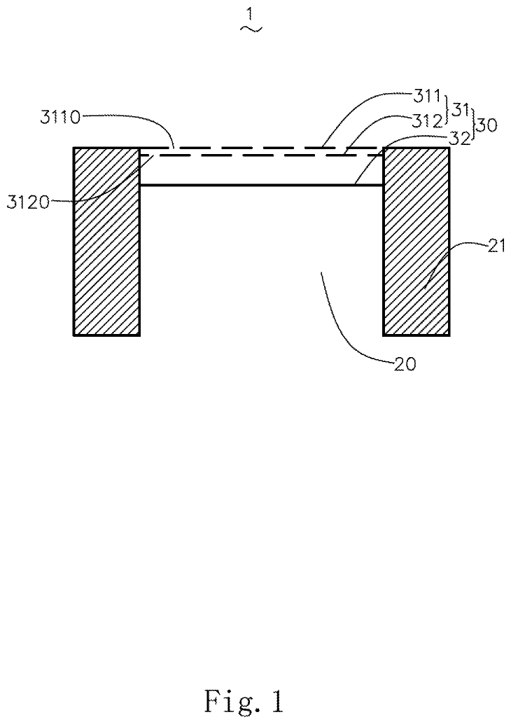

As shown in FIG. 1, the present disclosure discloses a MEMS sensor 1 including a substrate 21 with a back cavity 20 and a capacitive system 30 arranged on the substrate 21. The capacitive system 30 includes a first back plate assembly 31 and a diaphragm 32 opposite to the first back plate assembly 31. The first back plate assembly 31 includes a first back plate 311 and a second back plate 312, the first back plate 311 is spaced apart from the second back plate 312. The first back plate 311 includes a plurality of a first back plate holes 3110, the second back plate 312 includes a plurality of a second back plate holes 3120, each of the first back plate holes 3110 and each of the second back plate holes 3120 opposite to the first back plate holes 3110 are staggered with each other in a vibration direction of the diaphragm 32, staggered back plate holes could play a role of dustproof. The first back plate assembly 31 is located on a side of the diaphragm 32 far away from the back cavity 20. In the other embodiment, the first back plate assembly could be located on a side of the diaphragm close to the back cavity.

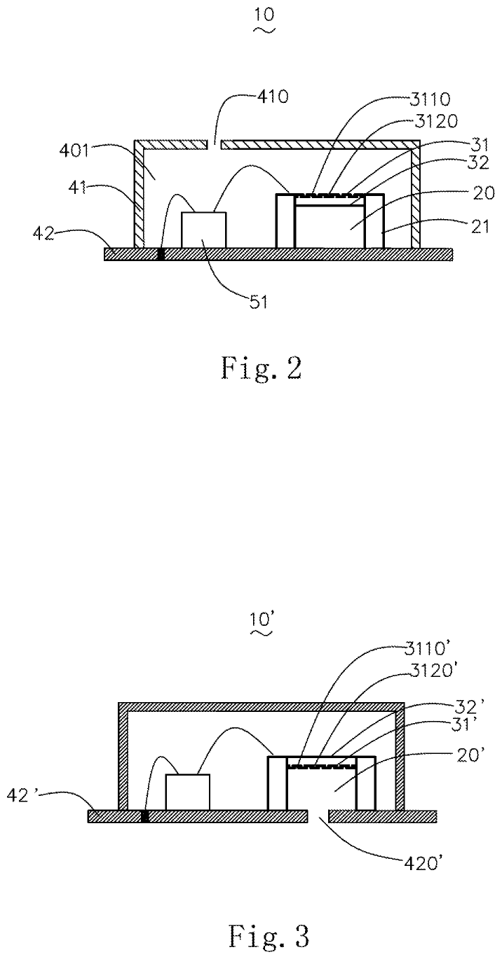

As shown in FIG. 2, the MEMS sensor 1 of the above structure can also be applied in a MEMS microphone 10, the MEMS microphone 10 includes a shell 41 and a base 42 enclosed with the shell 41 for forming an accommodation space 401, the MEMS sensor 1 is arranged in the accommodation space 401 and fixed with the base 42. If an inlet hole 410 communicated with accommodation space 401 is formed on the shell 41, the first back plate assembly 31 is located on the side of the diaphragm 32 far away from the substrate 21, that is the first back plate hole 3110 and the second back plate hole 3120 are closer to the inlet hole 410 than the diaphragm 32, and the first back plate holes 3110 and the second back plate holes 3120 are staggered with each other to plate the role of dustproof, thereby avoiding the dust to enter into the inside of the MEMS sensor 1. In the other embodiment, as shown in FIG. 3, the inlet hole 420′ communicated with the back cavity 20′ is formed on the base 42′, the first back plate assembly 31′ is located on the side of the diaphragm 32′ close to the base 42′, that is the first back plate hole 3110′ and the second back plate hole 3120′ are closer to the inlet hole 420′ than the diaphragm 32′, and the first back plate holes 3110′ and the second back plate holes 3120′ are staggered with each other to plate the role of dustproof, thereby avoiding the dust to enter into the inside of the MEMS sensor.

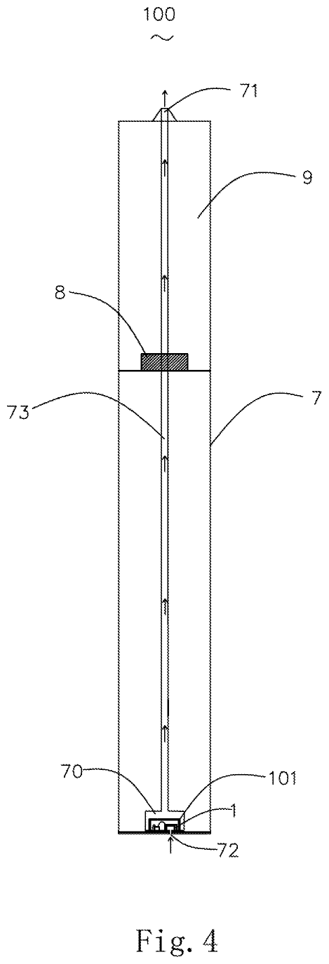

As shown in FIG. 4, the MEMS sensor 1 of the above structure can also be applied in an electronic cigarette 100. The electronic cigarette 100 includes a housing 7 with a smoking port 71 passing through an upper end thereof, an atomizer 8 received in the housing 7 and spaced apart from the smoking port 71, an e-liquid chamber 9 located between the atomizer 8 and the smoking port 71, a first receiving room 70 communicating with the smoking port 71, and a MEMS air flow sensor 101 located in the first receiving room 70. The MEMS air flow sensor 101 is welded and fixed in the first receiving room 70 of the housing 7. Smoke oil is injected into the e-liquid chamber 9, the first receiving room 70 is located at a bottom end of the housing 7 and communicates with the smoking port 71 through a flue 73, a connecting hole 72 is provided passing through the end of the housing 7, the connecting hole 72 communicates with the outside and the MEMS sensor 1.

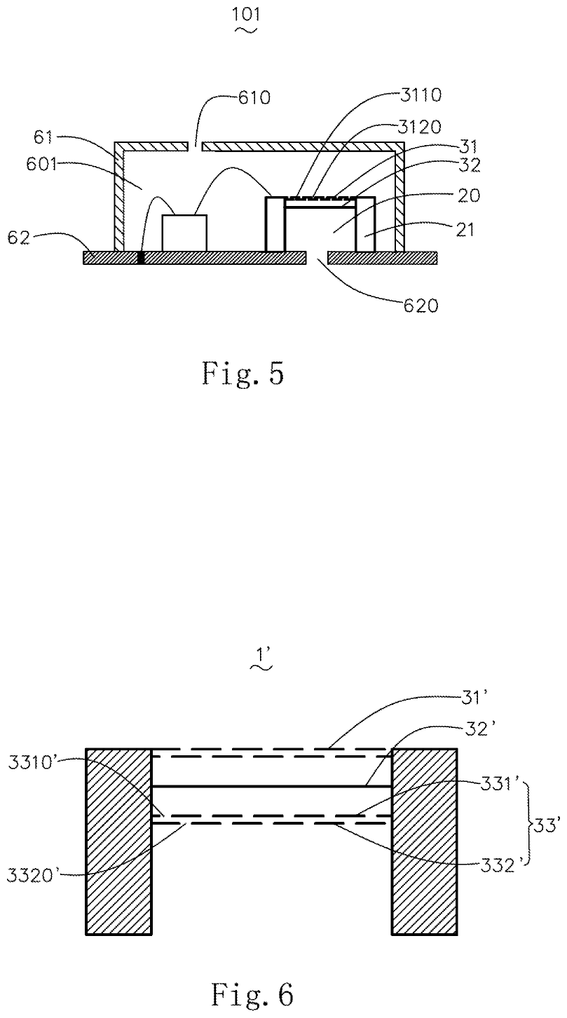

As shown in FIG. 5, the MEMS air flow sensor 101 includes a printed circuit board 62, a frame 61 connected with the printed circuit board 62 and forming a second receiving room 601 with the printed circuit board 62, and the MEMS sensor 1 as above, the MEMS sensor 1 is fixed with the printed circuit board 62. The frame 61 is provided with a first through hole 610 communicating with the first receiving room 71 and the second receiving room 72, the printed circuit board 62 is provided with a second through hole 620 communicating with the back cavity 20 and the outside. The first back plate holes 3110 and the second back plate holes 3120 are staggered with each other to plate the role of dustproof, thereby avoiding the dust to enter into the inside of the MEMS sensor 1.

In addition, some consumers have the habit of spitting back smoke during the smoking process, and this behavior will make the smoke enter inside the MEMS airflow sensor 101 along the flue 73, the smoke is a kind of aerosol, because the first back plate hole 3110 and the second back plate hole 3120 are small and staggered with each other, the distance between the first back plate 311 and the second back plate 312 is less than 1 μm (i.e. the size of aerosol molecules), when the aerosol passes, the liquid condensed into the aerosol in the MEMS sensor 1 will only adhere to the first back plate 311, the second back plate 312, and between the first back plate 311 and the second back plate 312, and the material condensed down by the aerosol is smoke oil, which has a large tension and will not enter the gap between the first back plate assembly 31 and the diaphragm 32 during actual use, thus not causing the first back plate assembly 31 and the diaphragm 32 to 31 and diaphragm 32 adsorbed together to appear self-starting phenomenon.

Further, in other embodiments, as shown in FIG. 6, the MEMS sensor 1′ further includes a second back plate assembly 33′, the first back plate assembly 31′ and the second back plate assembly 33′ are located on each side of the diaphragm 32′, the second back plate assembly 33′ includes a third back plate 331′ and a fourth back plate 332′ spaced from each other, a plurality of a third back plate holes 3310′ are formed in the third back plate 331′, a plurality of a fourth back plate holes 3320′ are formed in the fourth back plate 332′, the third back plate holes 3310′ and the fourth back plate holes 3320′ are staggered with each other in the vibration direction of the diaphragm 33′. And a distance between the third back plate 331′ and the fourth back plate 332′ is smaller than 1 μm, which can further act as a dustproof and aerosol into the MEMS sensor 1′.

The first housing cavity 70 is located at the bottom end of the housing 7 and is connected to the smoking port 71 through the flue 73. The bottom end of the housing 7 is also provided with a first through hole 72 connecting the outside world to the MEMS sensor 1.

Compared with the related art, since the first back plate and the second back plate hole are staggered with each other to play a dust-proof role, avoiding the dust to enter the inside of the MEMS sensor.

The above descriptions are merely some of the embodiments of the present disclosure. It should be pointed out that for those of ordinary skill in the art, improvements can be made without departing from the inventive concept of the present disclosure, shall fall within the scope of the present disclosure.

What is claimed is:

1. A MEMS sensor, comprising:
a substrate with a back cavity, and
a capacitive system arranged on the substrate, comprising a first back plate assembly and a diaphragm opposite to the first back plate assembly, wherein
the first back plate assembly comprises a first back plate and a second back plate, the first back plate is spaced apart from the second back plate, the first back plate comprises a plurality of a first back plate holes, the second back plate comprises a plurality of a second back plate holes, each first back plate hole and each second back plate hole are staggered with each other in a vibration direction of the diaphragm.

2. A MEMS microphone, comprising:
a shell,
a base enclosed with the shell to form an accommodation space, and
the MEMS sensor as described in claim 1 located in the accommodation space, wherein
the MEMS sensor is fixed with the base, a sound inlet hole is formed in the shell or the base.

3. The MEMS microphone described as claim 2, wherein the sound inlet hole is formed in the shell, the first back plate assembly is located on a side of the diaphragm far away from the substrate.

4. The MEMS microphone described as claim 2, wherein the sound inlet hole is formed in the base, the sound inlet hole is in communication with the back cavity, the first back plate assembly is located on a side of the diaphragm close to the base.

5. An electronic cigarette, comprising,
a housing with a smoking port passing through an upper end thereof,
an atomizer received in the housing and spaced apart from the smoking port,
an e-liquid chamber located between the atomizer and the smoking port,
a first receiving space communicating with the smoking port, and
an MEMS air flow sensor located in the first receiving space, wherein
the MEMS air flow sensor comprises a printed circuit board, a frame connected with the printed circuit board to form a second receiving space, the MEMS sensor as described in claim 1 is fixed with the printed circuit board, the frame comprises a first through hole in communicating with the first receiving space and the second receiving space, a second through hole is formed in the printed circuit board and in communicating with the back cavity and the outside.

6. The electronic cigarette described as claim 5, wherein a distance between the first back plate and the second back plate is smaller than 1 μm.

7. The electronic cigarette described as claim 5, wherein the capacitive system further comprises a second back plate assembly, the first back plate assembly and the second back plate assembly are located on each side of the diaphragm, the second back plate assembly comprises a third back plate and a fourth back plate spaced from each other, a plurality of a third back plate holes are formed in the third back plate, a plurality of a fourth back plate holes are formed in the fourth back plate, the third back plate holes and the fourth back plate holes are staggered with each other in the vibration direction of the diaphragm.

8. The MEMS microphone described as claim 7, wherein a distance between the third back plate and the fourth back plate is smaller than 1 μm.
